(19) United States
(12) Patent Application Publication
(10) Pub. No.: US 2015/0187549 A1
(43) Pub. Date: Jul. 2, 2015

(54) MAGNETRON SPUTTERING APPARATUS

(71) Applicant: TOKYO ELECTRON LIMITED, Tokyo (JP)

(72) Inventors: Toru Kitada, Nirasaki City (JP); Kanto Nakamura, Nirasaki City (JP); Atsushi Gomi, Nirasaki City (JP); Tetsuya Miyashita, Nirasaki City (JP)

(21) Appl. No.: 14/404,143

(22) PCT Filed: Mar. 28, 2013
(86) PCT No.: PCT/JP2013/002113

§ 371 Date: Nov. 26, 2014

(30) Foreign Application Priority Data
May 31, 2012 (JP) 2012-125493

(51) Int. Cl. H01J 37/34

(52) U.S. Cl. CPC H01J 37/3455; H01J 2237/332

(57) ABSTRACT

To provide technology that can increase the productivity of an apparatus when magnetron sputtering is carried out using a target formed from magnetic material. The present disclosure is an apparatus provided with: a cylindrical body that is a target formed from magnetic material, disposed above a substrate; a rotating mechanism that rotates this cylindrical body around the axis of the cylindrical body; a magnet array provided inside a hollow part of the cylindrical body; and a power supply that applies voltage to the cylindrical body. Furthermore, the magnet array has a cross sectional profile, orthogonal to the axis of the cylindrical body. Thus, even if a target with a comparatively large thickness is used, reductions in the intensity of the magnetic field that leaks from the target can be suppressed, and local progress in erosion can be suppressed.

### TECHNICAL FIELD

The present disclosure relates to a magnetron sputtering apparatus for forming a film on a substrate.

### BACKGROUND

Many magnetic materials are used in forming a magnetic random access memory (MRAM), which is expected to become the next generation memory or a hard disc drive. Most magnetic materials are typically formed as a thin film on a substrate by sputtering. The MRAM is a memory element, in which an insulating film is interposed between magnetic films made of a ferromagnetic material. Depending on whether magnetization directions of the magnetic films are the same or opposite, the memory element can be read when a change in the amount of current is detected at the insulating film.

The sputtering is generally performed by a magnetron sputtering method using an apparatus having a circular or rectangular plate-shaped target 101 made of a magnetic material installed in a vacuum vessel, and a plurality of magnets 102 disposed on a back side of the target 101, as shown in FIG. 24. In FIG. 24, reference numeral 103 designates a water cooling plate configured to cool the target 101, and reference numeral 104 designates a support member of the magnets 102.

A leakage magnetic field from the magnet 102 causes a magnetic field to be generated along the bottom surface of the target 101. Then, if a negative DC power or high frequency power, for example, is supplied to the target 101, an electric field is generated perpendicular to the magnetic field and an inert gas such argon (Ar) gas introduced into the vacuum vessel becomes ionized. The perpendicular electric field then leads to a cycloidal motion of secondary electrons in plasma and the secondary electrons stay in the vicinity of the target 101. Thus, the efficiency of inert gas ionization can be improved and high density plasma can be formed in the vicinity of the target. As a result, it is possible to increase the film forming rate of the magnetic film on the substrate and reduce the impact onto the substrate due to the entrapment of the secondary electrons in the vicinity of the target 101. In addition, it is possible to obtain an effect, such as a reduction of infiltration of an inert gas into the magnetic film due to a decrease in pressure of the inert gas, i.e., reduction of infiltration of impurities into the film.

However, since the target 101 is made of a magnetic material, the magnetic field generated from the magnets 102 is absorbed in the target 101. The absorption amount depends on a saturated magnetic flux density or a magnetic permeability of the target 101. That is, a magnetic field that is not totally absorbed by the target 101 but is leaked to generate the plasma. In general, the strength of a leakage magnetic field necessary to generate the plasma as above is equal to or greater than 200 gausses.

However, in order to improve the productivity of the apparatus, it is necessary to reduce a frequency of exchange of the target 101. For that reason, increasing a thickness of the target 101 was considered. However, if the target 101 has an increased thickness, the strength of the leakage magnetic field would decrease and thus, it is difficult to sufficiently increase the thickness. Techniques have been implemented such that a magnetic circuit configured by the magnets 102 or a volume of the magnets 102 obtains a high magnetic field strength, or those having a relatively high magnetic flux density, such as Nd—Fe—B (neodymium-iron-boron), have been used as a cathode magnet. However, in spite of such coping methods, it is difficult to sufficiently increase the thickness of the target 101. For example, when the target 101 is formed with a Co35Fe65 alloy having a saturated magnetic flux density (Bs) of 2.4 T (a numerical value is represented in atomic percentage (at %)), an upper limit of its thickness is 5 mm or so.

In addition, there is a problem in that an erosion rate is accelerated in the magnetic material target 101. FIG. 25 illustrates a profile of erosion 105 that is changed as the target 101 is sputtered. In FIG. 25, upper, intermediate and lower parts represent profiles of early, middle and late stages of the erosion 105, respectively. The profiles of the target 101 are shown in the right side of the figure. The profiles of a target 106 made of a nonmagnetic material, as a comparative example, are shown in the left side. For the nonmagnetic material target 106, since no change in a magnetic field leaking from the magnets 102 occurs throughout the early to late stages, the erosion 105 grows at a constant rate.

However, for the magnetic material target 101, if the erosion 105 is formed and the thickness of the target 101 is varied in its plane, the strength of the leakage magnetic field at a portion of the target 101 having a small thickness is increased more than the other portions of the target 101. Thus, this makes a magnetic flux 107 concentrated at the small thickness portion. As a result, the small thickness portion is sputtered. Then, since this phenomenon becomes conspicuous as the sputtering proceeds, the erosion 105 exhibits a sharp gradient as shown in the profile at the late stage. That is, for the target 101, since the erosion 105 grows largely at specific portions in the plane, sufficient utilization efficiency is not obtained as compared to the nonmagnetic material target 106. As a result, a frequency of exchange of the target 101 is increased.

Japanese Laid-open Patent Publication No. H06-17247 discloses a technique of forming a film on a substrate by sputtering with the substrate passing over a rotating cylindrical target. In addition, Japanese Laid-open Patent Publication No. H11-29866 also discloses a technique of sputtering performed on a substrate disposed to be fixed in the horizontal direction with respect to a cylindrical target. Further, Japanese Laid-open Patent Publication No. 2009-1912 discloses a technique of sputtering performed on a rotating wafer with a plate-shaped target inclined with respect to the wafer. However, since these documents do not take notice of the above problem generated due to the use of the magnetic material target, such a problem cannot be sufficiently solved. Moreover, Japanese Laid-open Patent Publication No. H06-17247 has a problem in that a process chamber is enlarged since a region for moving the substrate needs to be secured.

### SUMMARY

The present disclosure has been made in consideration of the above-mentioned points, and provides some embodiments of a magnetron sputtering apparatus capable of improving productivity of an apparatus when magnetron sputtering is performed using a target made of a magnetic material.

In the present disclosure, there is provided a magnetron sputtering apparatus of forming a film on a substrate mounted on a rotatable mounting part inside a vacuum vessel by a magnetron sputtering method, the magnetron sputtering apparatus including:

a cylindrical body that is a target made of a magnetic material and disposed above the substrate such that a central axis of the cylindrical body is offset from a central axis of the substrate in a direction along a surface of the substrate;

a rotary mechanism configured to rotate the cylindrical body around the axis of the cylindrical body;

a magnet arrangement assembly installed in a hollow portion of the cylindrical body; and a power supply part configured to apply a voltage to the cylindrical body,

wherein a cross section of the magnet arrangement assembly perpendicular to the axis of the cylindrical body is shaped such that a central portion of the magnet arrangement assembly protrudes toward a peripheral surface of the cylindrical body more than both ends of the magnetic arrangement assembly in a circumferential direction of the cylindrical body.

Specific embodiments of the present disclosure are, for example, as follows:

(a) The magnetic material of the target comprises metal or alloy containing at least one of elements consisting of 3d transition metals of Fe, Co and Ni as a main component.

(b) There is provided a moving mechanism configured to move the magnet arrangement assembly in an axial direction of the cylindrical body.

(c) There is provided a moving mechanism configured to move the magnet arrangement assembly in the circumferential direction of the cylindrical body.

(d) The cross section of the magnet arrangement assembly perpendicular to the axis of the cylindrical body is shaped such that a contour of a side of the magnet arrangement assembly facing the inner peripheral surface of the cylindrical body is formed in the shape of a curved line or a polygonal line along the inner peripheral surface of the cylindrical body from both the ends toward the central portion.

(e) The cross section of the magnet arrangement assembly perpendicular to the axis of the cylindrical body is shaped such that a contour of a side of the magnet arrangement assembly facing the inner peripheral surface of the cylindrical body is formed in the shape of a step having multiple stages from both the ends toward the central portion.

(f) The magnet arrangement assembly comprises a plurality of magnets, a distance between each magnet and the peripheral surface of the cylindrical body is 15 mm or less.

(g) The magnet arrangement assembly comprises a first magnet, second magnets installed with the first magnet interposed therebetween such that a magnetic pole of sides of the second magnets facing the peripheral surface of the cylindrical body is different from a magnetic pole of a side of the first magnet facing the inner peripheral surface of the cylindrical body, and third magnets installed between the first magnet and the second magnets such that a magnetic pole direction of the third magnets faces from any one side of the first magnet and the second magnets toward the other side in order to enhance a magnetic field generated by the first and second magnets, and

the third magnets protrude toward the peripheral surface of the cylindrical body more than the second magnets, and the first magnet protrudes toward the peripheral surface of the cylindrical body more than the third magnets.

According to the present disclosure, a cylindrical body that is a target made of a magnetic material which is obliquely disposed with respect to a substrate and rotates around an axis is installed. In addition, a cross section of a magnet arrangement assembly perpendicular to the axis of the cylindrical body is shaped such that the central portion of the magnet arrangement assembly protrudes toward a peripheral surface of the cylindrical body more than both ends of the magnet arrangement assembly in the circumferential direction of the cylindrical body. Thus, even though the target has a large thickness, the strength of the magnetic field leaking from the magnet arrangement assembly to the outside of the cylindrical body can be restrained from being weakened. In addition, local erosion can also be restrained from being grown at the target. Accordingly, it is possible to improve the productivity of the apparatus by restraining an increase in the frequency of exchange of the target.

### BRIEF DESCRIPTION OF THE DRAWINGS

FIG. 1 is a longitudinal sectional side view of a magnetron sputtering apparatus according to one embodiment of the present disclosure.

FIG. 2 is a transversal sectional plan view of the magnetron sputtering apparatus.

FIG. 3 is a perspective view showing magnets constituting a magnet arrangement assembly and a target.

FIG. 4 is a longitudinal sectional side view of the magnet arrangement assembly and the target.

FIG. 5 is a view illustrating the operation of a stage and the target when a film is formed.

FIGS. 6 to 8 are views illustrating a state in which erosion grows in the target.

FIG. 9 is a transversal sectional plan view of another magnetron sputtering apparatus.

FIG. 10 is a view illustrating the operation of the magnet arrangement assembly of another magnetron sputtering apparatus.

FIG. 11 is a transversal sectional plan view of still another magnetron sputtering apparatus.

FIG. 12 is a side view showing another configuration example of the magnet arrangement assembly.

FIGS. 13 to 15 are side views showing still another configuration example of the magnet arrangement assembly.

FIG. 16 is a timing chart illustrating the operations of respective components of the magnetron sputtering apparatus.

FIG. 17 is a view illustrating examples of an angle of magnets.

FIG. 18 is a longitudinal sectional side view of a magnetron sputtering apparatus according to another embodiment of the present disclosure.

FIG. 19 is a transversal sectional plan view of the magnetron sputtering apparatus.

FIG. 20 is a timing chart illustrating the operations of respective components of the magnetron sputtering apparatus.

FIGS. 21 to 22 are schematic views showing a result of an evaluation test.

FIG. 23 is a graph showing results of evaluation tests.

FIG. 24 is a view illustrating a configuration of a target of a conventional apparatus.

FIG. 25 is a view illustrating states in which erosion grows in a magnetic material target and a nonmagnetic material target.

### DETAILED DESCRIPTION

### First Embodiment

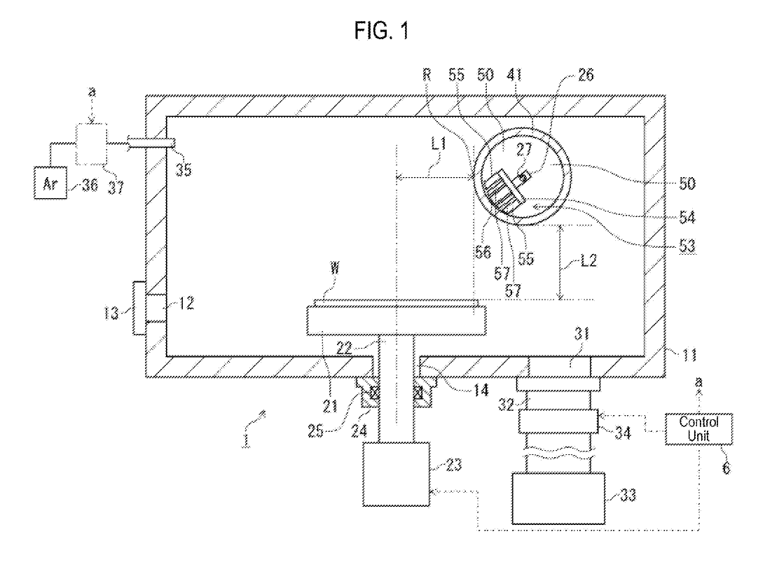

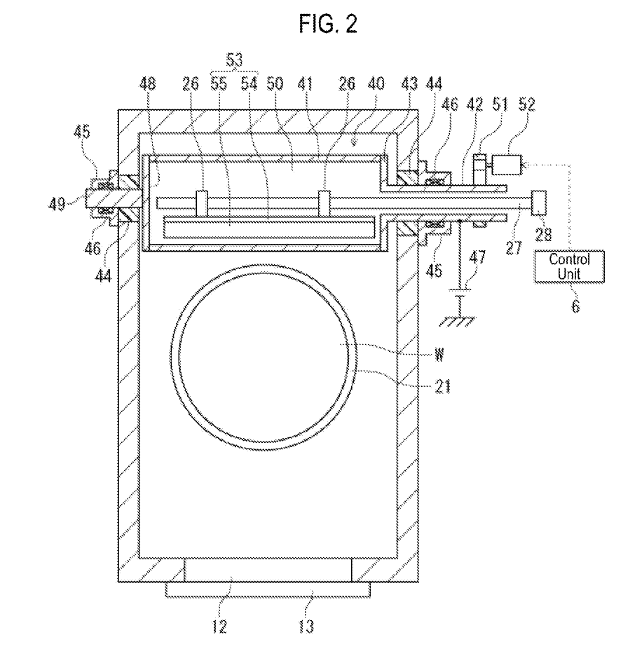

A magnetron sputtering apparatus 1 according to one embodiment of the present disclosure will be described with reference to the drawings. FIG. 1 is a longitudinal sectional side view of the magnetron sputtering apparatus 1. FIG. 2 is a transversal sectional plan view of the magnetron sputtering apparatus 1. Reference numeral 11 designates a vacuum vessel, which is made of, e.g., aluminum (Al), and is grounded. Reference numeral 12 designates a transfer port of a wafer W as a substrate, which is opened at a sidewall of the vacuum vessel 11 and is opened and closed by an opening/closing mechanism 13.

A circular stage 21 is installed inside the vacuum vessel 11. A semiconductor wafer (hereinafter, simply referred to as a wafer) W that is a substrate is horizontally mounted on a surface of the stage 21. The wafer W, for example, having a diameter of 150 mm to 450 mm, may be mounted on the stage 21. One end of a shaft part 22, which extends in the vertical direction, is connected to the central portion of the rear surface of the stage 21. In order to enable a film thickness distribution to be finely controlled, the stage 21 is configured to have a lifting mechanism and a height of the stage 21 may be changed according to processing conditions. The other end of the shaft part 22 extends to the outside of the vacuum vessel 11 through an opening 14 formed at a bottom portion of the vacuum vessel 11 and is connected to a rotary driving mechanism 23. The stage 21 is configured to be rotatable, e.g., at 0 rpm to 300 rpm, around the vertical axis by the rotary driving mechanism 23 through the shaft part 22. A cylindrical rotary seal 24 is installed around the shaft part 22 so as to block a gap between the vacuum vessel 11 and the shaft part 22 from the outside of the vacuum vessel 11. In FIG. 1, reference numeral 25 designates a bearing installed at the rotary seal 24.

A heater (not shown) is installed inside the stage 21, thereby heating the wafer W at a predetermined temperature. In addition, the stage 21 is provided with push-up pins (not shown) configured to transfer the wafer W between the stage 21 and an external transfer mechanism (not shown) of the vacuum vessel 11.

An exhaust port 31 is opened at a lower portion of the vacuum vessel 11. The exhaust port 31 is connected to one end of an exhaust pipe 32, and the other end of the exhaust pipe 32 is connected to an exhaust pump 33. In FIG. 1, reference numeral 34 designates an exhaust amount adjustment mechanism, which is installed through the exhaust pipe 32 to serve to adjust an internal pressure of the vacuum vessel 11. A gas nozzle 35, which is a plasma generation gas supply part, is installed at an upper side of the sidewall of the vacuum vessel 11. The gas nozzle 35 is connected to a gas supply source 36 in which an inert gas such as Ar is reserved. In FIG. 1, reference numeral 37 designates a flow rate adjustment part including a mass flow controller, which controls the amount of the Ar gas supplied to the gas nozzle 35 from the gas supply source 36.

A target 41 that is a cylindrical body is installed along a horizontal axis inside the vacuum vessel 11. The target 41 is obliquely disposed with respect to the wafer W such that an end R of the target 41 adjacent to the central axis of the wafer W in the length direction of the target 41 is above the wafer W. The sputtered particles from the target 41 are emitted according to the cosine law. That is, a number of the sputtered particles are emitted in proportion to the cosine value of an angle of the direction in which the sputtered particles are emitted with respect to a normal line of the surface of the target 41 from which the sputtered particles are emitted. In the case where the target 41 is obliquely disposed with respect to the wafer W as described above, the sputtered particles can be incident on the wafer W from a wider range of the target 41 as compared with a case in which the target 41 is disposed directly above the wafer W. Thus, it is possible to deposit the sputtered particles on the wafer W with high uniformity by appropriately setting an offset distance and a TS distance, which will be described later. In addition, when the target 41 is made of an alloy, it is possible to enhance alloy composition uniformity of the film formed on the wafer W.

A distance L1 (referred to as an offset distance) in the horizontal direction between the target 41 and the central axis of the wafer W on the stage 21 is set to fall within a range of, for example, 0 mm to 300 mm. If a height between the lower end of the target 41 and the surface the wafer W mounted on the stage 21 is a TS distance L2, the TS distance L2 is set to fall within a range of, for example, 50 mm to 300 mm. The offset distance L1 and the TS distance L2 are determined according to a film thickness required for a magnetic film, a sputtering rate of the target 41 and the film quality.

The target 41 is made of any one material of Co—Fe—B (cobalt-iron-boron) alloy, Co—Fe alloy, Fe, Ta (tantalum), Ru, Mg, IrMn, PtMn and the like, for example, for constituting a MRAM element. More specifically, the target 41 is made of a metal or alloy containing at least one of elements consisting of 3d transition metals of Fe, Co and Ni (nickel) as a main component. In the case where the element is processed to be contained in a metal or alloy as a main component, the element is not infiltrated into the metal or alloy as impurities. Instead, being contained in a metal or alloy as a main component refers to, for example, the case where the element in the metal or alloy is proportional to being equal or greater than 10% of the entirety of the target 41.

As shown in FIG. 2, a cylindrical rotating axis 42 having both of its ends extending from the inside of the vacuum vessel 11 to the outside is installed along with the target 41. In the rotating axis 42, the end positioned inside the vacuum vessel 11 has an expanded diameter to form a flange 43 and blocks one end of the target 41. The rotating axis 42 is supported by the vacuum vessel 11 through an insulating member 44 configured to insulate the target 41 and the vacuum vessel 11 from each other. In addition, a cylindrical rotary seal 45 is installed in order to secure the air-tightness of the vacuum vessel 11 by blocking a gap (not shown) between the rotating axis 42 and the vacuum vessel 11 from the outside of the vacuum vessel 11. In the FIG. 2, reference numeral 46 designates a bearing which is installed at the rotary seal 45. The rotating axis 42 and the flange 43 are made of a conductive material and constitute an electrode 40 together with the target 41. A negative DC voltage is applied to the electrode 40 by a power supply part 47. However, a high frequency voltage may be applied instead of the DC voltage.

A circular metal lid 48 is installed in order to block the other end of the target 41. A rotating axis 49 extends from the central portion of the lid 48 toward the outside of the vacuum vessel 11 in the axial direction of the target 41. In order to block a gap between the rotating axis 49 and the vacuum vessel 11, a rotary seal 45 having a bearing 46 is installed in the same manner as the one end of the target 41. In the same manner as the rotating axis 42, the rotating axis 49 is supported by the vacuum vessel 11 through an insulating member 44. The vacuum vessel 11 and the electrode 40 are insulated from each other by the insulating member 44. Further, instead of the above configuration in which both the ends of the target 41 are respectively supported by the vacuum vessel 11 through the rotating axes 42 and 49, the target 41 may be supported by the vacuum vessel 11 only through the rotating axis 42 without installing the rotating axis 49.

A belt 51 is wound around the rotating axis 42 and is driven by a motor 52 constituting the rotary mechanism. Thus, the target 41 is rotated around the rotating axis 42. A magnet arrangement assembly 53 is installed at a hollow portion 50 of the target 41. The magnet arrangement assembly 53 is provided with a support plate 54 extending in the axial direction and, for example, magnets 55, 55, 56, 57 and 57 supported on the support plate 54. As viewed in the axial direction of the target 41, the respective magnets 55 to 57 are installed in parallel with each other, as viewed from the side of the hollow portion 50, in an obliquely downward direction facing toward the wafer W. Thus, the respective magnets 55 to 57 constitute a magnetic circuit.

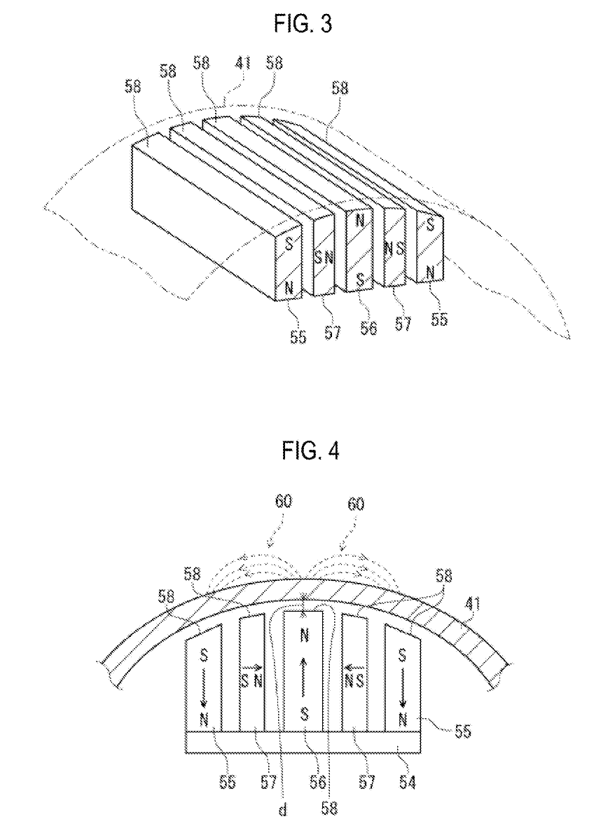

FIG. 3 shows a longitudinal sectional perspective view of the magnets 55 to 57, and FIG. 4 shows a longitudinal sectional side view of the magnets 55 to 57. In FIGS. 3 and 4, reference numeral 58 designates leading end surfaces of the magnets. The respective magnets 55 to 57 are disposed to be spaced apart from each other as viewed from the side. In addition, the magnets 57 and 57 are disposed on the left and right of the magnet 56 such that the magnet 56 is interposed therebetween. In addition, magnets 55 and 55 are also disposed on the left and right of the magnets 57 and 57 such that the magnets 57 are interposed therebetween. The magnet 56, as a first magnet, is configured to be rectangular in shape as viewed from the side. The magnets 55, as second magnets, and the magnets 57, as third magnets, are respectively configured in the shape of a trapezoid such that each leading end extending from the support plate 54 is an oblique side as viewed from the side.

The magnets 56 and 55 are magnets configured to generate magnetic flux 60 outside the target 41. A magnetic field direction (magnetic pole direction) of each of the magnets 56 and 55 is along the direction in which it extends from the support plate 54. A side of the magnet 56 facing the target 41 is the N-pole, and sides of the magnets 55 facing the target 41 are the S-pole. The magnets 57 are installed in order to enhance the magnetic flux 60 between the magnets 56 and 55. For this purpose, the magnetic pole direction of the magnets 57 is perpendicular to the magnetic pole direction of the magnets 56 and 55. In addition, the sides of the magnets 57 facing the magnet 56 are the N-pole. In FIG. 4, the respective magnetic pole directions of the magnets 55 to 57 are represented by solid arrows.

In addition, as the leading end surface 58 of each of the magnets 55 to 57 is configured to be further spaced apart from the support plate 54 toward the leading end surface 58 of the magnet 55 disposed at the central portion in the arrangement direction of the magnets 55 to 57, the leading end surface 58 of each of the magnets 55 to 57 further protrudes from the support plate 54 toward a peripheral surface of the target 41. That is, the leading end surface 58 of each of the magnets 55 to 57 appears to align with the inner periphery of the target 41 and is shaped in a polygonal line as viewed from the side. From another viewpoint, if a curved surface of the inner periphery of the target 41 is approximated to a straight line, each leading end surface 58 is installed to be parallel with the approximated straight line.

As the respective magnets are configured as described above, by making the distance between the magnets 55 and 56 and the target 41 decrease, the magnetic flux 60 outside the target 41 is enhanced. Further, as the action of the magnets 57 can be made relatively large, the magnetic flux 60 can be more enhanced. That is, the leakage magnetic field from the target 41 can be increased. In FIG. 4, a distance d between the leading end surface 58 of the magnet 56 and the inner peripheral surface of the target 41 is set to fall within a range of, for example, 15 mm or less. A distance between the leading end surfaces 58 of the other magnets 55 and 57 and the inner peripheral surface of the target 41 is also set to fall within a range of, for example, 15 mm or less, in the same manner as above.

Returning to FIG. 2, brackets 26 are connected to the support plate 54. The brackets 26 are supported by being connected to a support rod 27 axially extending within the target 41 and the rotating axis 42. An end 28 of the support rod 27 extends to the outside of the vacuum vessel 11 and is supported, for example, by a wall portion (not shown).

The magnetron sputtering apparatus 1 is provided with a control unit 6. The control unit 6 includes a program for transmitting a control signal to each component of the magnetron sputtering apparatus 1. This program transmits the control signal configured to control the operation of each component of the magnetron sputtering apparatus 1 so as to perform the film formation processing described later. Specifically, the operation of supplying power to the electrode 40 from the power supply part 47, the operation of adjusting a flow rate of Ar gas by the flow rate adjustment part 37, the operation of adjusting an internal pressure of the vacuum vessel 11 by the exhaust amount adjustment mechanism 34, the operation of rotating the stage 21 by the rotary driving mechanism 23, the operation of rotating the target 41 by the motor 52, and the like are controlled by the control signals. The program is stored in a storage medium, such as a hard disc, a compact disc, a magneto-optical disc, a memory card, or the like, and is installed to a computer from the storage medium.

Subsequently, the operation of the above-described magnetron sputtering apparatus 1 will be described. The transfer port 12 of the vacuum vessel 11 is opened. The wafer W is loaded onto the stage 21 by cooperation between the external transfer mechanism (not shown) and push-up pins. Subsequently, the transfer port 12 is closed. The Ar gas is supplied into the vacuum vessel 11, and the exhaust amount is controlled by the exhaust amount adjustment mechanism 34. Thus, the interior of the vacuum vessel 11 is maintained at a predetermined pressure.

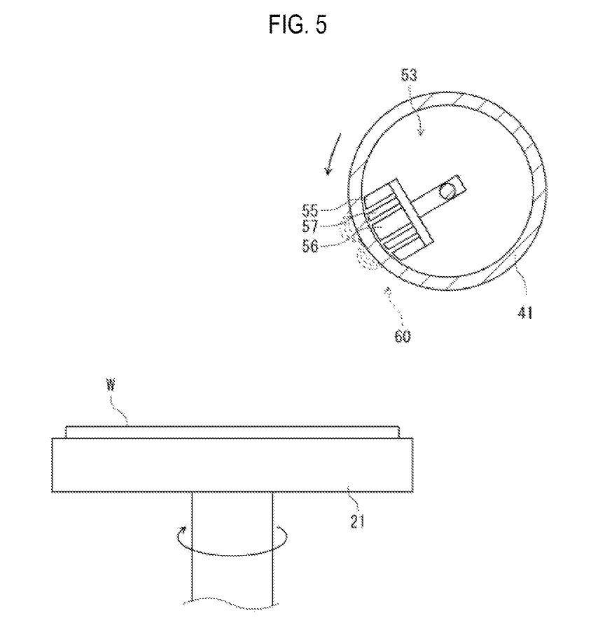

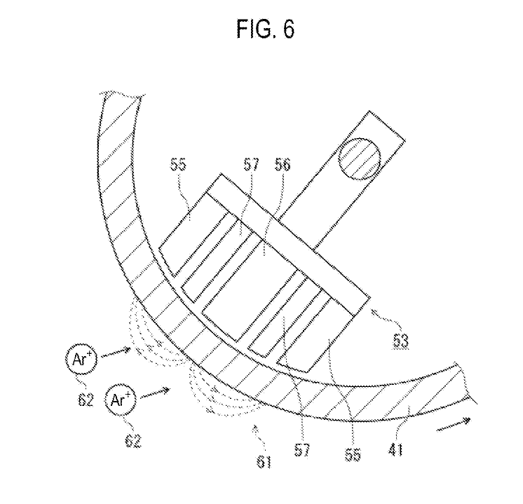

Then, as shown by arrows in FIG. 5, while the stage 21 is rotated around the vertical axis, the target 41 is rotated around the axis by the motor 52. A negative DC voltage is then applied from the power supply part 47 to the target 41, such that an electric field is generated around the target 41. Then, the Ar gas is ionized by the electric field to generate electrons. In the meantime, a magnetic field from the magnets 55 to 57, which is not absorbed by the target 41 but leaks to the outside, causes a leakage magnetic field constituting the magnetic flux 60 to be generated between the magnets 55 to 57 as shown by dotted lines in FIG. 5. Thus, a horizontal magnetic field 61 is generated in the vicinity of the surface (sputtered surface) of the target 41 as shown in FIG. 6.

In this way, the magnetic field and the electric field in the vicinity of the target 41 cause the electrons to be accelerated and drifted. Then, the electrons having sufficient energy caused by the acceleration also collide with the Ar gas and cause ionization thereof. Thus, this effect generates plasma and Ar ions 62 in the plasma are sputtered onto the target 41. In addition, secondary electrons generated by the sputtering are captured by the horizontal magnetic field and also contribute to the ionization of the Ar gas. Accordingly, an electron density is increased to generate high density plasma.

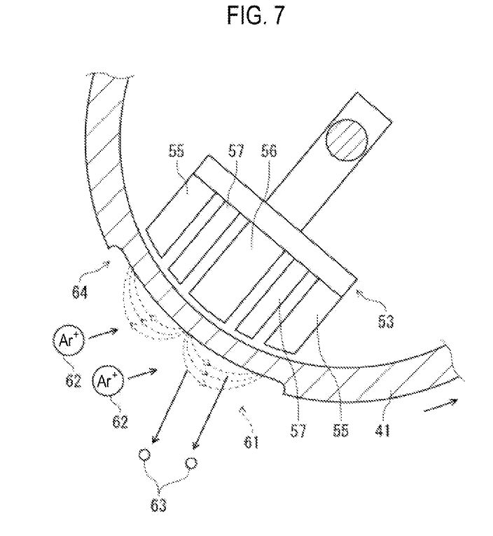

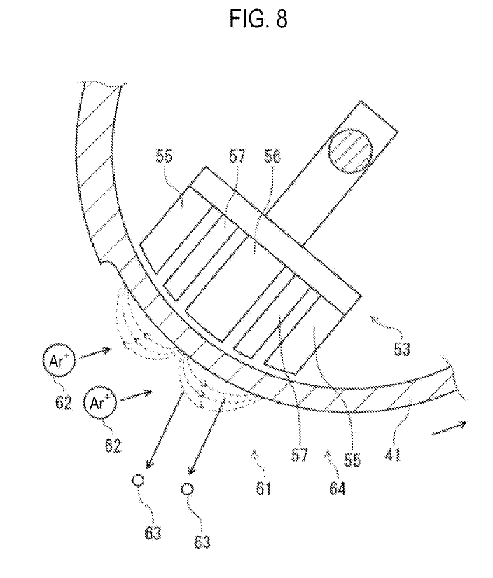

FIGS. 6 to 8 are schematic views showing a surface state of the target 41 varying over time. As shown in FIGS. 6 and 7, the target 41 is sputtered by the Ar ions 62 and sputtered particles 63 are emitted to form erosion 64. Since the target 41 is rotated relative to the magnets 55 to 57, a sputtered portion of the target 41 is displaced as shown in FIGS. 7 and 8 and the erosion 64 is formed to be spread in the circumferential direction of the target 41. Accordingly, the strength of the leakage magnetic field is prevented from being rapidly increased. As a result, it is possible to restrain the erosion 64 from locally growing toward the thickness direction of the target 41.

The sputtering of the target 41 more rapidly proceeds at a portion in which a horizontal component of the leakage magnetic field with respect to the surface of the target 41 is stronger. Thus, a large amount of the sputtered particles 63 are emitted from the corresponding portion. The emitted sputtered particles 63 are incident on and attached to the surface of the rotating wafer W. By offsetting a position at which the sputtered particles 63 are incident in the circumferential direction of the wafer W, the sputtered particles are supplied to the entire circumferential direction of the wafer W. Thus, a magnetic film is formed. When the power supply part 47 is turned on and a predetermined time then passes, the power is turned off to stop the generation of plasma and the supply of the Ar gas. Then, the vacuum vessel 11 is exhausted with a predetermined exhaust amount. The wafer W is unloaded from the vacuum vessel 11 in the reverse operation to the loading.

According to the magnetron sputtering apparatus 1, the cylindrical target 41 made of a magnetic material is sputtered while rotating around the axis. The sputtered particles are incident on the wafer W rotating around the central axis to perform the forming of a film. With this configuration, since it is possible to restrain the erosion of the target 41 from locally growing, utilization efficiency of the target 41 is improved. In addition, as viewed in the axial direction of the target 41, the magnet arrangement assembly 53 is configured such that the central portion of the target 41 protrudes out to be longer than either ends of the target 41 toward the inner peripheral surface of the target 41. With this configuration, since the strength of the magnetic field leaking from the target 41 can be made large, it is possible to relatively increase the thickness of the target 41. Therefore, since the number of the wafers W which can be processed by one target 41 is increased, a frequency of exchange of the target 41 is restrained. As a result, the productivity of the magnetron sputtering apparatus 1 can be improved.

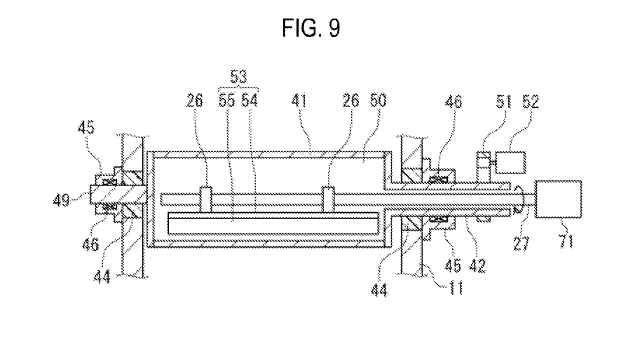

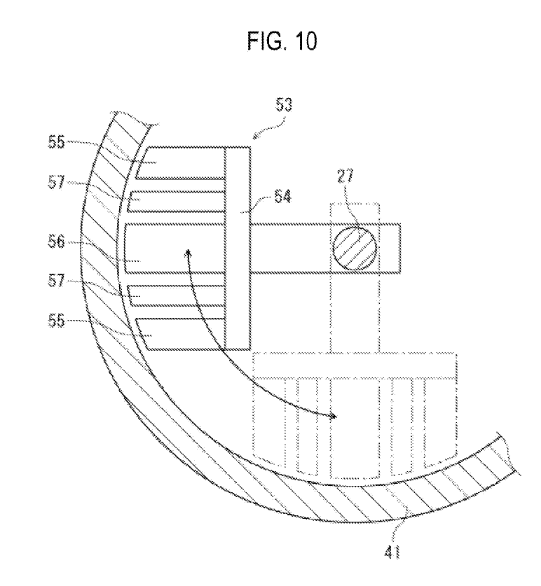

In the first embodiment, as the target 41 is obliquely disposed with respect to the wafer W and the wafer W is rotated when a film is formed, the in-plane film thickness uniformity of the wafer W is promoted. Thereafter, examples of the apparatus for further improving the film thickness uniformity will be described. FIG. 9 shows a first modification of the magnetron sputtering apparatus 1. The first modification is different from the above embodiment in that an end of the support rod 27 is connected to a rotary mechanism 71. In addition, the magnet arrangement assembly 53 may be rotated around the axis of the target 41, independent from the target 41. With this configuration, as shown in FIG. 10, a slope of the magnet arrangement assembly 53 may be changed.

For example, according to processing conditions such as an internal pressure of the vacuum vessel 11, a material of the target 41 and a voltage applied to the target 41 when a film is formed, an angle of the sputtered particles incident on the wafer W from the target 41 is changed. Accordingly, appropriate slopes of the magnets 55 to 57 corresponding to a variety of combinations of the pressures, the materials and the applied voltages are acquired in advance by experiments. Then, the memory of the control unit 6 stores a database in which the pressures, the materials, the applied voltages and the slopes of the magnets 55 to 57 correspond to one another. Then, if before the wafer W is processed, a user sets the pressure, material and applied voltage for performing the processing at the control unit 6, an appropriate slope of the magnets 55 to 57 is determined based on the database. Thereafter, the rotary mechanism 71 rotates the support rod 27, the magnets 55 is fixed at the determined slope, and then, the wafer W is processed.

In addition, when the rotary mechanism 71 is installed as described above, instead of the slope fixed during the processing of the wafer W, the slope of the magnets 55 to 57 may be continuously changed. For example, as shown in FIG. 10, the slope of the magnets 55 is changed such that a state represented by a solid line in which the magnets 55 to 57 are horizontal and a state represented by a chain line in which the magnets 55 to 57 face downward are alternately repeated. In addition, the memory of the control unit 6 stores data of moving speeds at respective points of a moving route of the magnets 55 to 57 which correspond to the respective processing conditions, instead of the slopes of the magnets 55 to 57. Further, if the user sets processing conditions, the magnets 55 to 57 move along the respective points of the moving route at a moving speed corresponding to the processing conditions. In this way, a film thickness distribution of the wafer W can be controlled.

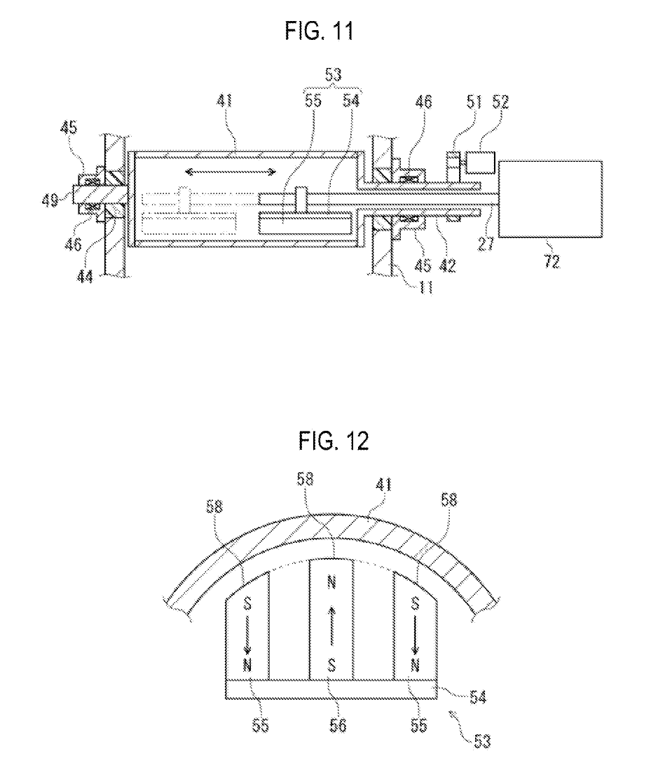

Furthermore, FIG. 11 shows a second modification of the magnetron sputtering apparatus 1. In this second modification, the magnet arrangement assembly 53 is sized so as to be moved back and forth inside the target 41 in its length direction. Further, the support rod 27 is advanced and retreated in its length direction by a moving mechanism 72, such that a position of the magnet arrangement assembly 53 may be changed. In the same manner as in the first modification, according to processing conditions, the processing may be performed while the position of the magnet arrangement assembly 53 is fixed. Further, during the processing, the magnet arrangement assembly 53 may be continuously moved back and forth. In addition, moving speeds of the magnet arrangement assembly 53 at respective points along the movement route may be set according to the processing conditions.

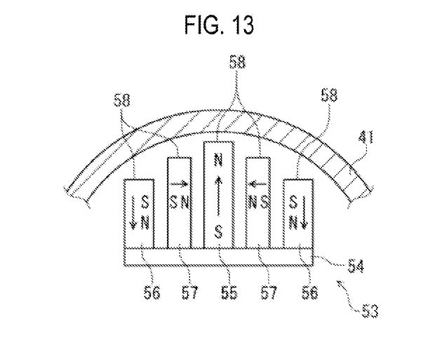

The configuration of the magnet arrangement assembly 53 is not limited to the above example. For example, as shown in FIG. 12, a contour of the leading end surface 58 of the magnets 55 and 56 may be shaped in a curve as viewed from the axial direction of the target 41. Further, the number of magnets constituting the magnet arrangement assembly 53 may be arbitrary if the horizontal magnetic field can be generated with respect to the target 41 as described above. More specifically, two magnets may be disposed such that one magnet is interposed therebetween, the inner magnet and the outer magnets each face in a direction opposite to the target surface, and the number of the magnets need to be three or more as shown in FIG. 12. That is, the magnets 57 for enhancing a magnetic field may not be installed. Further, in the figures after FIG. 12, the magnetic pole directions of the respective magnets are represented by arrows in the same manner as FIG. 4. In addition, as shown in FIG. 13, from both ends of the magnet arrangement assembly 53 toward its central portion, the magnets may be configured to have a step shape having the respective leading end surfaces 58 formed to face the target 41.

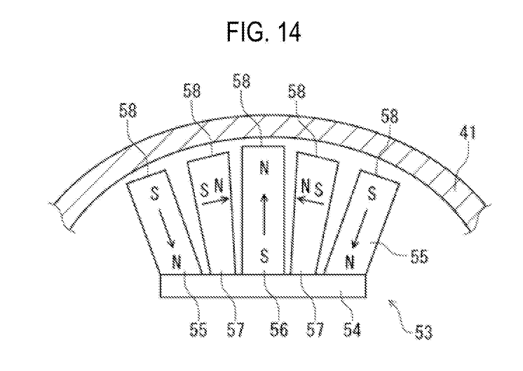

In addition, as shown in FIG. 14, the magnets 55 to 57 may be configured to radially extend from the support plate 54. In this example, as viewed from the side, a width of the magnet 57 is gradually increased toward the target 41. The other magnets 55 and 56 are not limited to those each having a constant width in the extending direction in the same manner as the magnets 57. Further, if a magnetic pole direction of the magnets 55 is vertical, in this example, a magnetic pole direction of each magnet 57 is set to be inclined from the magnets 55 toward the magnet 56. In this way, the magnetic pole direction of the magnets 57 is not limited to being perpendicular to the magnetic pole direction of the magnets 55 and 56.

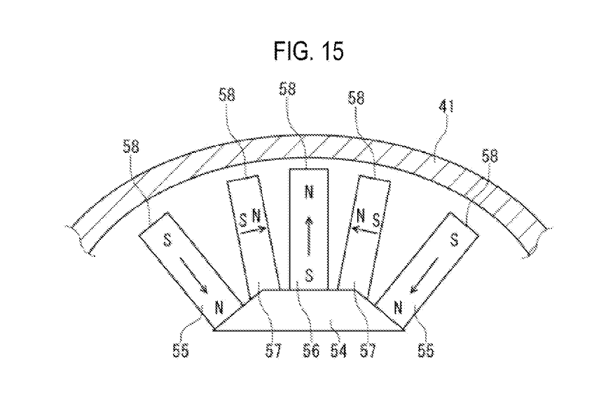

Further, while in each of the above examples, the support plate 54 is configured in the shape of a rectangle as viewed from the side, the present disclosure is not limited to such configuration. FIG. 15 shows an example in which the support plate 54 is configured in the shape of a trapezoid as viewed from the side. The magnet 56 extends from the upper face of the trapezoid. The magnets 55 and 55 radially extend from the oblique sides of the trapezoid. The magnets 57 radially extend from angled portions defined by the upper face and the oblique sides. As the support plate 54 is configured as described above, the magnet can be manufactured to be shaped in a simple rectangular parallelepiped. Thus, the manufacturing cost of the magnet can be reduced. Furthermore, the magnets 55 and 56 having the same shape may be used. Accordingly, it is possible to reduce an effort of adjusting the shape of each magnet when the magnetron sputtering apparatus is manufactured. The surface of the support plate 54 on which the magnets 55 to 57 are installed is not limited to these examples and may be, for example, a curved surface. Also, the surface of the support plate 54 may be configured to have any shape according to the shape of the magnets 55 to 57.

However, in the examples shown in the respective figures, the magnets 57 may not be installed. In addition, the leading end surface 58 of the magnets 57 may be configured to be restrained from protruding toward the inner peripheral surface of the target 41 more than the leading end surface 58 of the magnet 56. However, as already described above, in order to enhance the leakage magnetic field, it is effective that the magnets 57 are installed and the leading end surfaces 58 thereof are configured to protrude toward the peripheral surface more than the leading end surface 58 of the magnet 56.

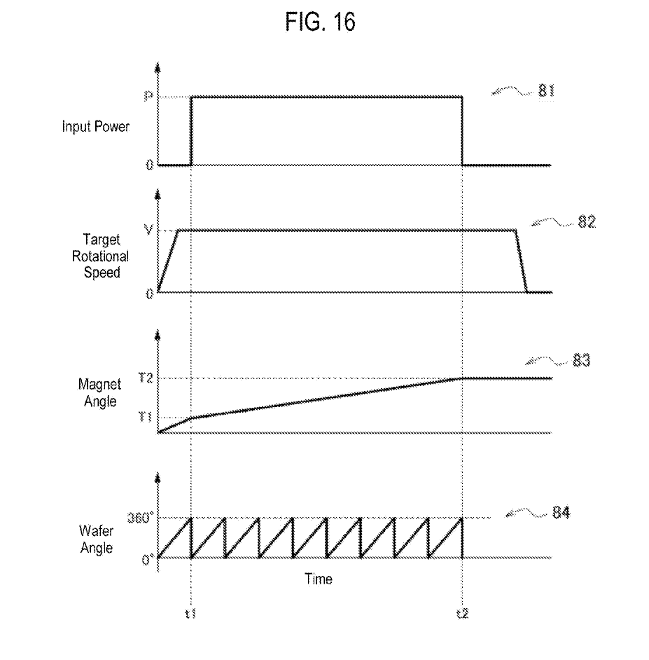

An example of the processing performed using the magnetron sputtering apparatus 1 of the first modification illustrated in FIGS. 9 and 10 will be described in more detail referring to a timing chart of FIG. 16. Four graphs 81 to 84 of this timing chart show the operations of the respective components of the magnetron sputtering apparatus 1 from before the processing of a wafer W until the processing of the wafer W is completed. The graph 81 indicates a timing at which power is applied to the target 41 by the power supply part 47. The graph 82 indicates a rotational speed of the target 41. The graph 83 indicates an angle of one magnet of the magnet arrangement assembly 53. The graph 84 indicates an angle of the wafer W.

The respective graphs 81 to 84 will be further described. The vertical axis of the graph 81 represents the power input to the target 41. When the power input is turned on, a power of P watt is supplied to form a film on the wafer W. The magnitude of the power P is arbitrarily set. The vertical axis of the graph 82 represents the rotational speed of the target 41. During the film formation processing, the target 41 is rotated at a constant speed V, for example. The same portion of the target 41 must not be sputtered continuously for a long time. Also, if the rotational speed of the target 41 is too high, the action of this rotation increases the number of particles scattered in a direction offset from the wafer W among the particles scattered from the target 41. Therefore, in some embodiments, the rotational speed V is relatively low and specifically falls within a range of, for example, 0 rpm or more to 10 rpm or less.

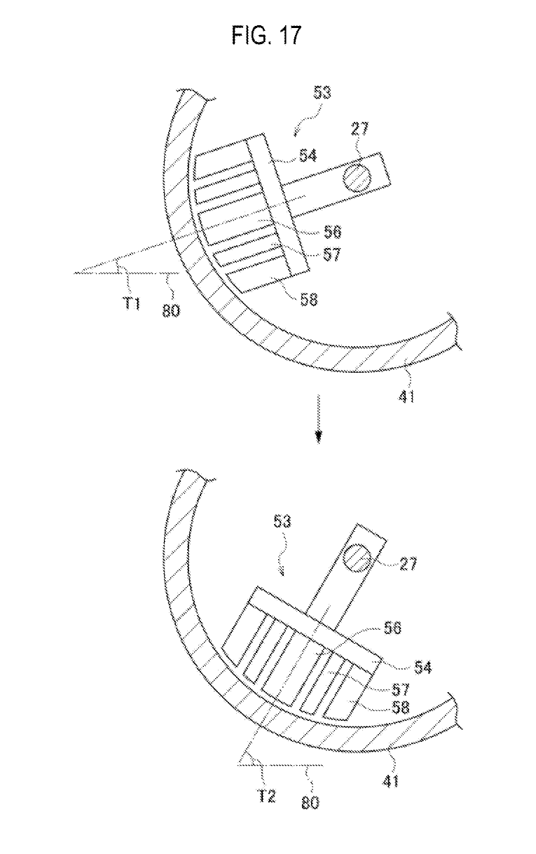

The vertical axis of the graph 83 represents the angle of the magnet. The angle of the magnet is, for example, an angle of a direction in which one magnet constituting the magnet arrangement assembly 53 extends from the support plate 54 with respect to the horizontal plane. The angle of the magnet at the initiation of the film formation processing is set to be T1, and the angle of the magnet at the termination of the film formation processing s set to be T2. FIG. 17 shows an example of the angles T1 and T2. In FIG. 17, reference numeral 80 designates the horizontal plane. The angle T1 and a range of the angle T1 to the angle T2 are appropriately set according to a material of the target 41 or film forming conditions. The film forming conditions include a thickness of a film formed on the wafer W, the power input to the target 41, and a processing pressure in the vacuum vessel 11. If the moving speed of the magnet arrangement assembly 53 is too high, the magnetic field over the surface of the target 41 becomes unstable. Thus, in some embodiments, the moving speed of the magnet arrangement assembly 53 is relatively low. Specifically, the magnet arrangement assembly 53 moves, for example, at 1.5 degree/sec to 10 degree/sec. In addition, the moving direction of the magnet arrangement assembly 53 during the film formation processing may be the same as the rotational direction of the target 41 or the reverse direction thereof.

The vertical axis of the graph 84 represents the angle of the wafer W. The angle of the wafer W is an angle of the wafer W mounted on the stage 21 which is set to 0 degree (equals to 360 degrees in one revolution) when a cutout (notch) formed at a side end of the wafer W is in a predetermined direction. In order to make a uniform film thickness distribution of a film formed while the wafer W rotates one revolution, in some embodiments, the wafer W is rotated a plurality of times, for example, eight times or more, during the film formation processing. However, if the rotational speed of the wafer W is too high, particles incident toward the wafer W bounce off due to the rotation of the wafer W. Thus, in some embodiments, the rotational speed is, for example, greater than 0 rpm to 120 rpm or less. Further, in order to improve uniformity of the film thickness distribution, in some embodiments, the angle of the wafer W at the initiation of the film formation processing coincides with the angle of the wafer W at the termination of the film formation processing.

The processing shown in the timing chart will be described in order. First, a user sets desired film forming conditions. According to the setting, a processing time is determined by the control unit 6. If the wafer W is loaded into the vacuum vessel 11, the rotational speed of the target 41 rises from 0 rpm to V rpm and the angle of the magnet changes from a predetermined angle to an angle of T1. Along with the rise of the rotational speed of the target 41 and the change of the magnet angle, the angle of the wafer W is set to be 0 degree (equals to 360 degrees in one revolution).

When the rotational speed of the target 41 reaches V rpm, the rise of the rotational speed is stopped, and the target 41 continuously rotates at V rpm. Then, if the angle of the magnet is T1 and the angle of the wafer W is 0 degree, the power is supplied to the target 41 to initiate the film formation processing (at a time t1 in FIG. 16). During the film formation processing, the target 41 continuously rotates at V rpm, and the magnet arrangement assembly 53 is continuously moved at the constant speed. Further, the wafer W also rotates continuously at a predetermined speed. After the supply of power to the target 41 is initiated, if the wafer W rotates, e.g., eight revolutions, and comes to the angle at the initiation of the film formation and the determined processing time passes, the supply of power to the target 41 is stopped. Thus, the film formation processing is terminated. Along with the stop of the supply of power, the rotation of the wafer W and the movement of the magnet arrangement assembly 53 are stopped (at a time t2 in FIG. 16). Thereafter, the rotation of the target 41 is also stopped.

In the film formation processing of the graph of FIG. 16, the magnet arrangement assembly 53 is moved in one direction such that the angle becomes from T1 to T2. However, the magnet arrangement assembly 53 may be moved back and forth as described in FIG. 10. That is, after the magnet arrangement assembly 53 is moved during the film formation processing such that an angle of the magnet of the magnet arrangement assembly 53 becomes, for example, from T1 to an arbitrary angle of T3, the moving direction may be reversed and the magnet arrangement assembly 53 may be moved such that the angle becomes from T3 to T1. Such movement may be repeatedly performed.

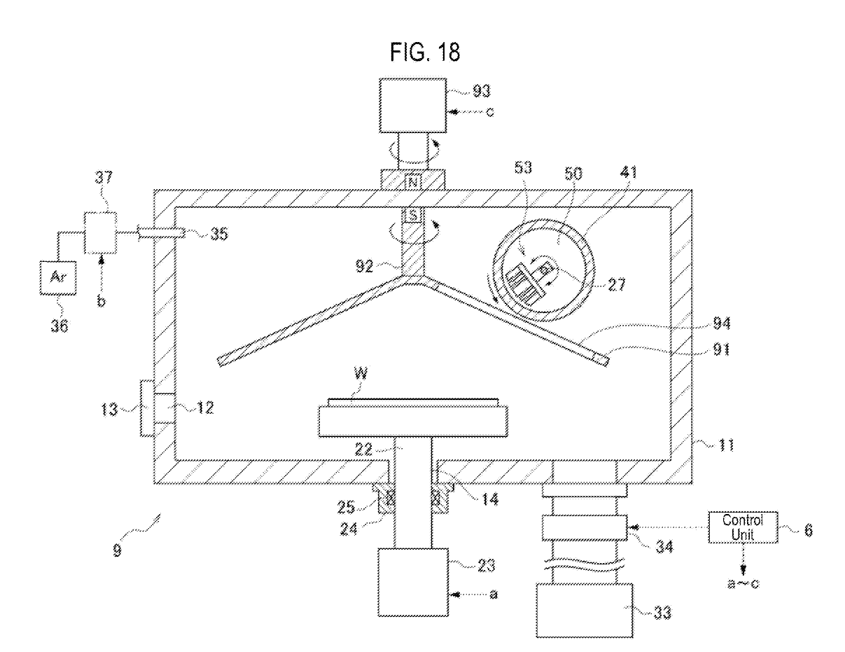

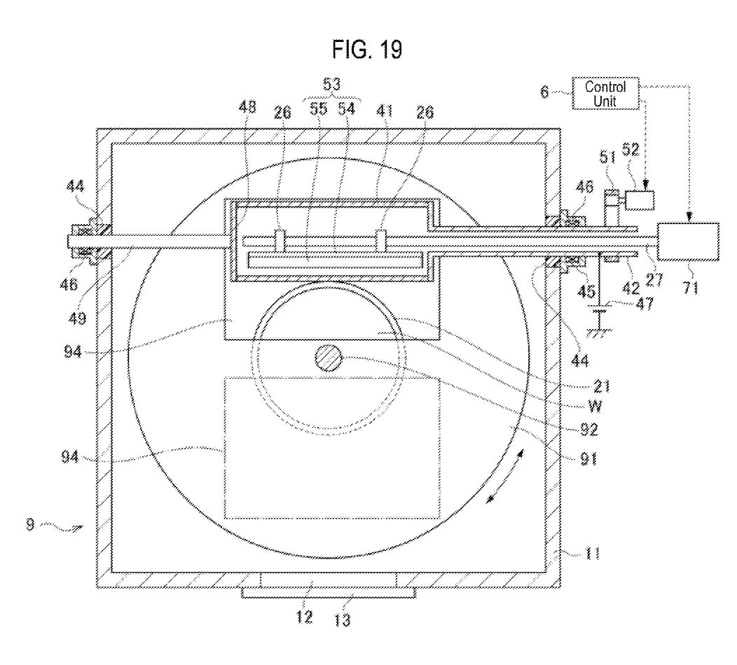

Subsequently, another configuration example of the magnetron sputtering apparatus will be described. FIGS. 18 and 19 are a longitudinal sectional side view and a transversal sectional plan view of a magnetron sputtering apparatus 9, respectively. The magnetron sputtering apparatus 9 has approximately the same configuration as the magnetron sputtering apparatus 1 according to the first modification described in FIGS. 9 and 10. There is a difference in that a shutter 91 is installed. The shutter 91 is formed in the shape of, for example, an umbrella, and is installed to divide the target 41 and the stage 21 from each other. A rotating axis 92 is connected to the upper central portion of the shutter 91. The rotating axis 92 is configured to be rotatable by a rotary mechanism 93 installed at the outside of the vacuum vessel 11. The rotary mechanism 93 rotates the rotating axis 92 using magnetic force to rotate the shutter 91.

The shutter 91 has an opening 94 formed therein. When the film formation processing is performed, in order that the particles scattered from the target 41 are supplied to the wafer W, the opening 94 is positioned below the target 41. Such a position is represented by a solid line in FIG. 19. The state where the opening 94 is in such a position is an open state of the shutter 91. When the film formation processing is not performed, in order that the target 41 and the wafer W are separated from each other, the opening 94 is positioned to be offset from below the target 41. This position is represented by a chain line in FIG. 19. The state where the opening 94 is in the position is a closed state of the shutter 91.

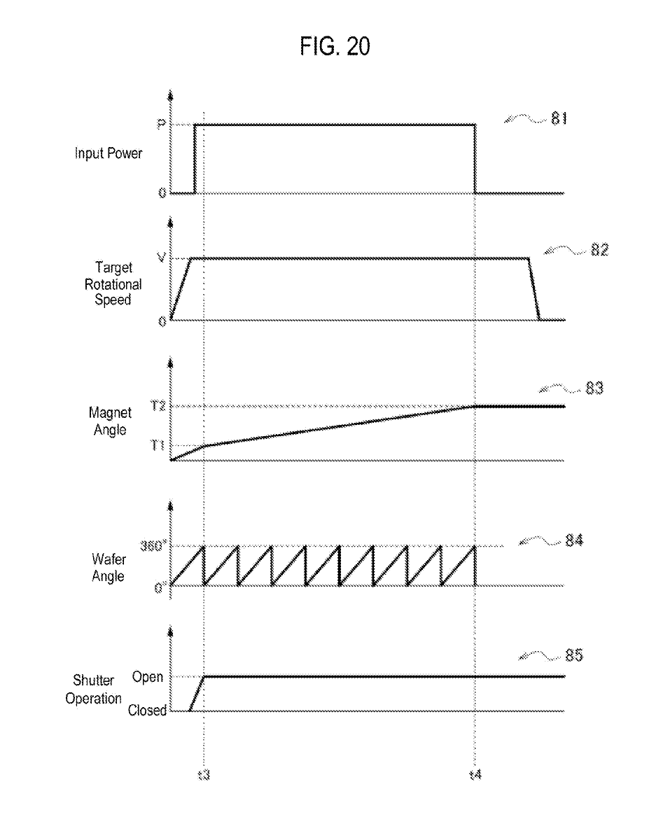

FIG. 20 is a timing chart illustrating an example of the operations of the respective components of the magnetron sputtering apparatus 9. The timing chart of FIG. 20 shows the aforementioned graphs 81 to 84 and a graph 85. The vertical axis of the graph 85 represents an opening/closing state of the shutter 91.

The operation of the magnetron sputtering apparatus 9 illustrated in the timing chart of FIG. 20 will be described with a focus on differences from the operation of the first modification of the magnetron sputtering apparatus 1 already described. In the state where the shutter 91 is closed, the rotational speed of the target 41 is raised to V rpm. Along with that, an angle of the magnet is set to be T1 and the angle of the wafer W is set to 0 degree. If the rotational speed of the target 41 reaches V rpm, the power is supplied to the target 41 and the target 41 is sputtered. The shutter 91 causes the sputtered particles toward the wafer W to be blocked. If the angle of the magnet is T1 and the angle of the wafer W is 0 degree, the shutter 91 is opened. Then, the sputtered particles pass through the opening 94 of the shutter 91 and are incident on the wafer W, thereby initiating the sputtering processing (at time t3). If, after the shutter 91 is opened, a processing time determined by the set film forming conditions passes, the supply of power to the target 41 is stopped. Thus, the film formation processing is stopped (at time t4).

That is, in the above processing, at the timing where the shutter 91 is opened, an initiation timing of the film formation processing is controlled. In the above processing, instead of stopping the supply of power, the shutter 91 may be closed to stop the film formation processing.

### Evaluation Test

### Evaluation Test 1

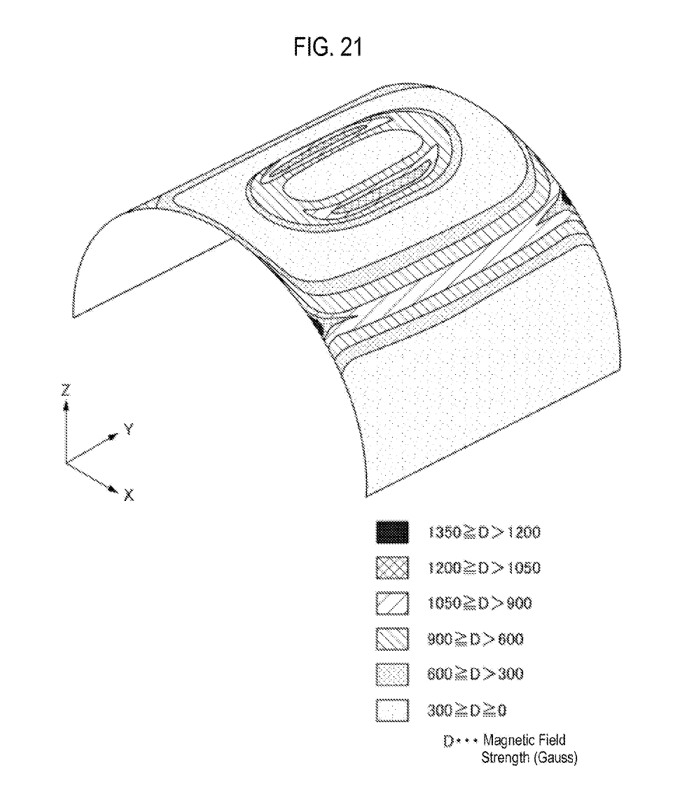

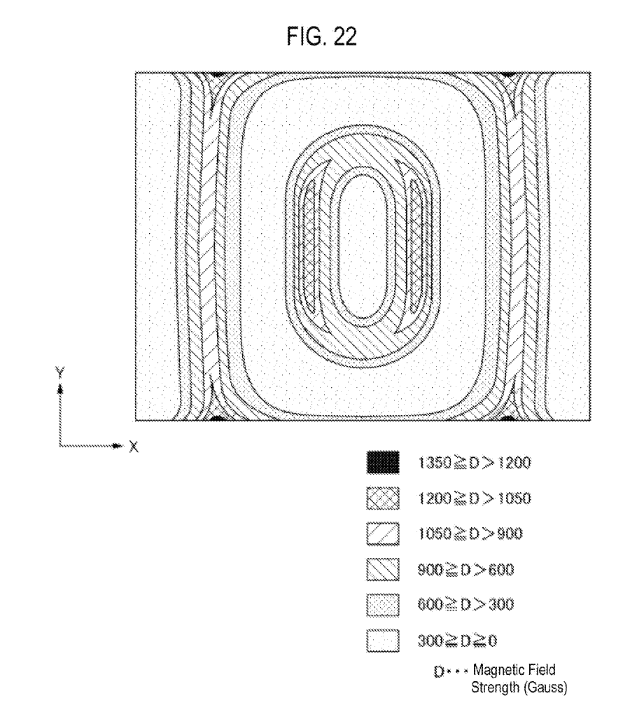

A leakage magnetic flux density distribution of the target 41 having the magnet arrangement assembly 53 already described was confirmed by a simulation. For the target 41, a material was Bs (brass), a magnetic flux density was set to 2.2 Teslas, and a thickness was set to 4 mm. FIGS. 21 and 22 show the simulation result. The figures show a magnetic flux density distribution at a surface spaced apart outward 0.5 mm from the surface of the target 41. In FIGS. 21 and 22, the arrangement direction of the magnets 55 to 57 is referred to as the X direction, the length direction of the cylinder of the target 41 is referred to as the Y direction, and a direction from a leading end side to a proximal end side of the magnets 55 to 57 is referred to as the Z direction. The X, Y, and Z directions are perpendicular to one another. FIG. 21 shows the magnetic flux density distribution as the target 41 is obliquely viewed. FIG. 22 shows the magnetic flux density distribution at the XY plane as the target 41 is viewed toward the Z direction.

A magnetic flux density distribution in an actual measurement result was obtained as a color image by computer graphics with a color and a color density varied according to a magnetic field strength. For convenience in showing FIGS. 21 and 22, instead of the color image, each region representing a predetermined range of a magnetic field strength is defined by contour lines. The defined regions are hatched with different patterns, respectively. A region having a magnetic field strength of more than 1200 gausses to 1350 gausses or less is marked in black. A region having a magnetic field strength of more than 1050 gausses to 1200 gausses or less is marked in a mesh pattern. A region having a magnetic field strength of more than 900 gausses to 1050 gausses or less is marked in sloped lines. A region having a magnetic field strength of more than 600 gausses to 900 gausses or less is marked in reverse-sloped lines. A region having a magnetic field strength of more than 300 gausses to 600 gausses or less is marked in relatively dark grayscale. A region having a magnetic field strength of 0 gauss or more to 300 gausses or less is marked in relatively light grayscale.

In general, in order to perform the magnetron sputtering by applying a DC voltage to the target as a magnetic material, a magnetic field strength leaking from the target is necessarily to become 500 gausses or more. As shown in FIGS. 21 and 22, a region having a magnetic field strength of 500 gausses or more was present at the surface of the target 41. In addition, the highest magnetic field strength of 1200 gausses or more was confirmed. That is, it showed that the magnet arrangement assembly 53 and the target 41 as already described were used to easily perform the film formation processing on the wafer W.

### Evaluation Test 2

As Evaluation Test 2-1, a simulation of performing the film formation processing was carried out as shown in the timing chart of FIG. 16. That is, in Evaluation Test 2-1, the magnet arrangement assembly 53 was set to be moved during the film formation processing. In addition, a film thickness distribution obtained at each portion of the wafer W by the film formation processing was calculated as a percentage, and 1-sigma (standard deviation) was calculated. Further, as Evaluation Test 2-2, a simulation of performing the film formation processing was carried out without moving the magnet arrangement assembly 53 during the film formation processing. Except that the magnet arrangement assembly 53 was not moved during the film formation processing, the simulation of Evaluation Test 2-2 was carried out under the same film forming conditions as Evaluation Test 2-1. Then, for a film thickness distribution obtained by the simulation, 1-sigma was calculated in the same manner as Evaluation Test 2-1.

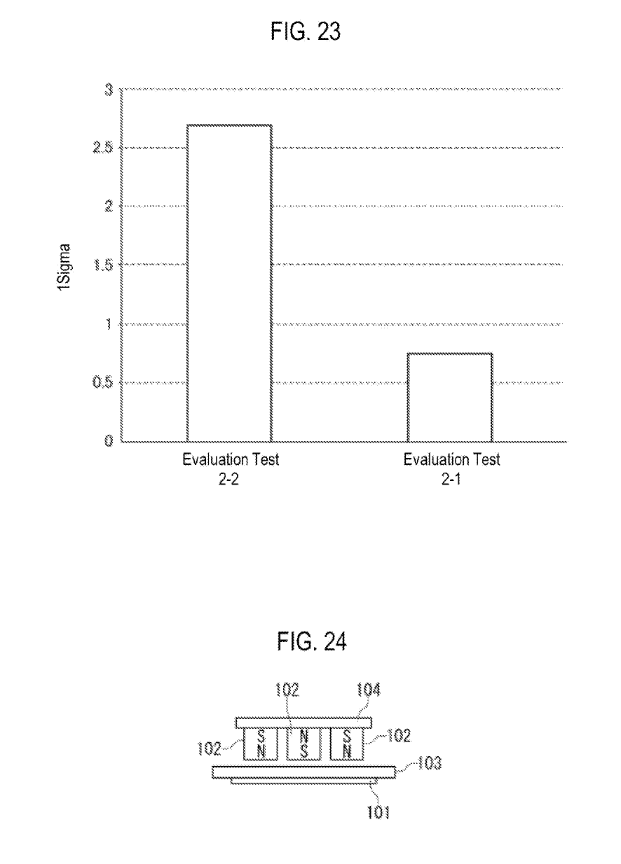

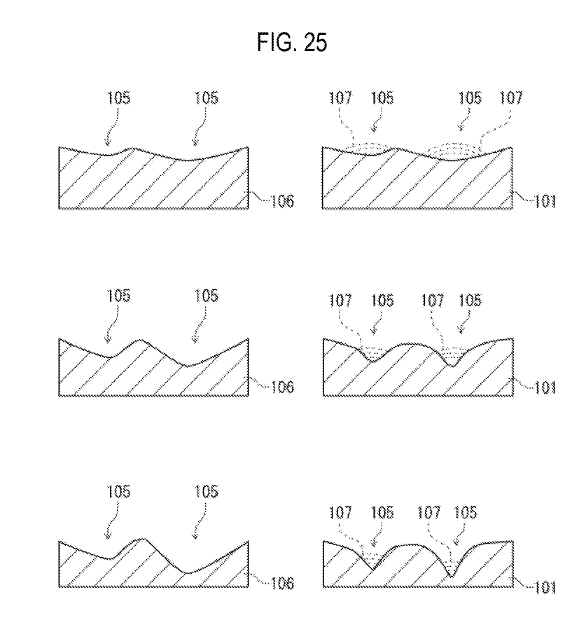

A bar graph of FIG. 23 shows results of Evaluation Tests 2-1 and 2-2. The vertical axis of the graph represents the 1-sigma. That is, the smaller a numerical value of the vertical axis is, the higher the film thickness uniformity at each portion of the wafer W is. Evaluation Test 2-1 has a 1-sigma of 0.75 or so, and Evaluation Test 2-2 has a 1-sigma of 2.75 or so. That is, Evaluation Test 2-1 has higher film thickness uniformity than Evaluation Test 2-2. Further, for arrangement of the magnets constituting the magnet arrangement assembly 53, a plurality of patterns were prepared. Evaluation Tests 2-1 and 2-2 were carried out using each pattern. Although the arrangement pattern of the magnets was changed, Evaluation Test 2-1 had higher film thickness uniformity than Evaluation Test 2-2. That is, it showed that the film thickness uniformity could be improved by moving the magnet arrangement assembly 53 during the film formation processing.

1. A magnetron sputtering apparatus of forming a film on a substrate mounted on a rotatable mounting part inside a vacuum vessel by a magnetron sputtering method, the magnetron sputtering apparatus comprising:
a cylindrical body that is a target comprising a magnetic material and disposed above the substrate such that a central axis of the cylindrical body is offset from a central axis of the substrate in a direction along a surface of the substrate;
a rotary mechanism configured to rotate the cylindrical body around the axis of the cylindrical body;
a magnet arrangement assembly installed in a hollow portion of the cylindrical body; and
a power supply configured to apply a voltage to the cylindrical body,
wherein a cross section of the magnet arrangement assembly perpendicular to the axis of the cylindrical body is shaped such that a central portion of the magnet arrangement assembly protrudes toward a peripheral surface of the cylindrical body by more than both ends of the magnetic arrangement assembly in a circumferential direction of the cylindrical body.

2. The magnetron sputtering apparatus of claim 1, wherein the magnetic material of the target comprises metal or alloy containing at least one of elements consisting of 3d transition metals of Fe, Co and Ni as a main component.

3. The magnetron sputtering apparatus of claim 1, further comprising a moving mechanism configured to move the magnet arrangement assembly in an axial direction of the cylindrical body.

4. The magnetron sputtering apparatus of claim 1, further comprising a moving mechanism configured to move the magnet arrangement assembly in the circumferential direction of the cylindrical body.

5. The magnetron sputtering apparatus of claim 1, wherein the cross section of the magnet arrangement assembly perpendicular to the axis of the cylindrical body is shaped such that a contour of a side of the magnet arrangement assembly facing the inner peripheral surface of the cylindrical body is formed in the shape of a curved line or a polygonal line along the inner peripheral surface of the cylindrical body from both the ends toward the central portion.

6. The magnetron sputtering apparatus of claim 1, wherein the cross section of the magnet arrangement assembly perpendicular to the axis of the cylindrical body is shaped such that a contour of a side of the magnet arrangement assembly facing the inner peripheral surface of the cylindrical body is formed in the shape of a step having multiple stages from both the ends toward the central portion.

7. The magnetron sputtering apparatus of claim 1, wherein the magnet arrangement assembly comprises a plurality of magnets, a distance between the magnet and the peripheral surface of the cylindrical body being 15 mm or less.

8. The magnetron sputtering apparatus of claim 1, wherein the magnet arrangement assembly comprises a first magnet, second magnets installed with the first magnet interposed therebetween such that a magnetic pole of sides of the second magnets facing the peripheral surface of the cylindrical body is different from a magnetic pole of a side of the first magnet facing the inner peripheral surface of the cylindrical body, and third magnets installed between the first magnet and the second magnets such that a magnetic pole direction of the third magnets faces from any one side of the first magnet and the second magnets toward the other side in order to enhance a magnetic field generated by the first and second magnets, and
the third magnets protrude toward the peripheral surface of the cylindrical body more than the second magnets, and the first magnet protrudes toward the peripheral surface of the cylindrical body more than the third magnets.
